(19) United States
(12) Patent Application Publication
(10) Pub. No.: US 2026/0068636 A1
(43) Pub. Date: Mar. 5, 2026

(54) ISOLATION PATTERN MODULE AND FABRICATING METHOD THEREOF AS WELL AS METHOD FOR MANUFACTURING ISOLATION PATTERN APPLYING THE SAME

(71) Applicant: UNITED MICROELECTRONICS CORP., Hsinchu (TW)

(72) Inventors: Kun-Yuan WU, Kaohsiung City (TW); Chen-Hsien Hsu, Hsinchu County (TW); Wei-Jen Wang, Tainan City (TW); Chien-Fu Chen, Miaoli County (TW); Ruei-Yau Chen, Pingtung County (TW); Cheng-Yang Tsai, Tainan City (TW); Yu-Pin Chou, Hsinchu City (TW); Cheng-Cheng Chuang, Taichung City (TW)

(21) Appl. No.: 18/916,204

(22) Filed: Oct. 15, 2024

(30) Foreign Application Priority Data
Sep. 3, 2024 (TW) 113133305

(51) Int. Cl. H01L 23/528; H01L 27/02

(52) U.S. Cl. CPC H01L 23/528; H10D 89/10

(57) ABSTRACT

An isolation pattern module for manufacturing an isolation pattern includes a first sub-isolation-pattern and a second sub-isolation-pattern. The sub-isolation-pattern includes a plurality of pattern units, and each of the pattern units has a pitch boundary to define a closed area. The second sub-isolation-pattern corresponds to the pitch boundary of each of the pattern units and overlaps the closed area.

This application claims the benefit of Taiwan Application Serial No. 113133305 filed at Sep. 3, 2024 the subject matter of which is incorporated herein by reference.

### BACKGROUND

### Technical Field

The disclosure relates to a system and method for functional design, comprehensive verification, and physical design (including layout, wiring, layout, design rule checking, etc.) of very large-scale integration (VLSI), and more particularly to an isolation pattern module and a method for realizing a well region isolation pattern in a semiconductor substrate during a semiconductor manufacturing process.

### Description of Background

In recent years, with the increasing critical-dimension (CD) miniaturization in VLSI, photolithography has become one of the most important steps in the semiconductor manufacturing process. Among them, the accuracy of the mask pattern plays a very important role.

Taking the semiconductor process of forming a well region isolation structure (or element) in a semiconductor substrate as an example, the traditional method is to define an isolation pattern by manually drawing a desired isolation figure, and the isolation pattern is then transferred into the semiconductor substrate to be integrated with a deep NWELL region located in the deeper portion of the semiconductor substrate to surround a space to be isolated, so as to achieve the predetermined isolation function. However, as the VLSI layout patterns become more and more complex, forming isolation patterns using traditional manual methods is not only difficult to standardize, but also revelry affect the processing accuracy and margin (process window) of the well isolation structure (or element).

Therefore, there is a need of providing an improved isolation pattern module and its fabricating method as well as a method for manufacturing an isolation pattern applying the same to obviate the drawbacks encountered from the prior art.

### SUMMARY

One aspect of the present disclosure is to provide an isolation pattern module for manufacturing an isolation pattern, wherein the isolation pattern module includes a first sub-isolation-pattern and a second sub-isolation-pattern. The sub-isolation-pattern includes a plurality of pattern units, and each of the pattern units has a pitch boundary to define a closed area. The second sub-isolation-pattern corresponds to the pitch boundary of each of the pattern units and overlaps the closed area.

Another aspect of the present disclosure to provide a fabricating method of an isolation pattern module, wherein the fabricating method includes steps as follows: Firstly, a plurality of pattern units are constructed, wherein each of the pattern units has a pitch boundary. Next, these pattern units are spliced to form a first sub-isolation pattern, and a closed area is defined by the pitch boundary of each of the pattern units. A second sub-isolation pattern is then constructed based on and overlapped with the closed area.

Yet another aspect of the present disclosure to provide a method for manufacturing an isolation pattern, wherein method includes steps as follows: Firstly, a plurality of pattern units are constructed, wherein each of the pattern units has a pitch boundary. The plurality of pattern units are then introduced into an electronic design automation (EDA) system using a plurality of instructions. Next, these pattern units are spliced to form a first sub-isolation pattern; and a second sub-isolation pattern is then constructed based on and overlapped with the closed area.

According to the above embodiments, an isolation pattern module, a fabrication method thereof, and a method for manufacturing an isolation pattern are provided by the present disclosure. An EDA software is used to construct at least one pattern unit (cell) according to the processing pitch, to make each of the pattern units having a pitch boundary. Next, a first sub-isolation pattern is formed by splicing the plurality of pattern units, in which the pitch boundaries of two adjacent pattern units are connected to each other to define a closed area. Subsequently, a second sub-isolation pattern is formed based on and overlapped with the closed area. The first sub-isolation pattern and the second sub-isolation pattern together form an isolation pattern module.

By using at least one standard cell designed from the beginning serving as a pattern unit, and in combine with the EDA system, at least one sub-isolation pattern can be formed more effectively through splicing a plurality of standard cells (pattern units). Multiple sub-isolation patterns can be then combined to form an isolation pattern module used to form isolation elements in a semiconductor substrate. It has the advantages of reducing manual operations, increasing the pattern design flexibility and variability, and improving the accuracy and margin (process window) of integrated circuits (ICs) manufacturing.

In one embodiment of the present disclosure, the solation pattern module includes a first sub-isolation pattern and a second sub-isolation pattern, by which a first well corresponding to the first sub-isolation pattern can be formed in a semiconductor substrate to define a closed circuit area; and a second well area corresponding to the second sub-isolation pattern below the first well can be formed to overlap the closed circuit area; thereby an isolation structure can be prepared.

### BRIEF DESCRIPTION OF THE DRAWINGS

The above objects and advantages of the present disclosure will become more readily apparent to those ordinarily skilled in the art after reviewing the following detailed description and accompanying drawings, in which:

FIG. 1A is a diagram illustrating the process for fabricating an isolation pattern module, according to one embodiment of the present disclosure;

FIG. 1B is a diagram illustrating the process for manufacturing an isolation structure in a semiconductor substrate using the isolation pattern module as depicted in FIG. 1A;

FIG. 2 is a diagram illustrating the flow chart of the method for fabricating the isolation pattern module as depicted in FIG. 1A;

FIG. 3 is a diagram illustrating the process for fabricating an isolation pattern module, according to another embodiment of the present disclosure;

FIG. 4 is a diagram illustrating the process for fabricating an isolation pattern module, according to yet another embodiment of the present disclosure; and

FIG. 5 is a diagram illustrating the process for fabricating an isolation pattern module, according to a further embodiment of the present disclosure.

### DETAILED DESCRIPTION

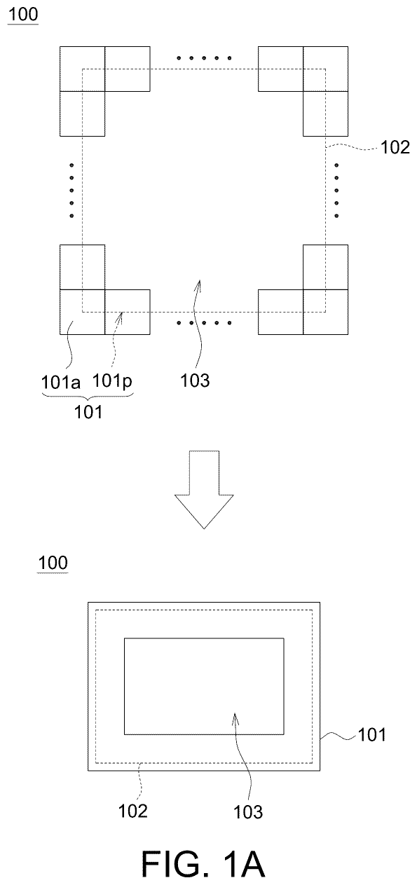

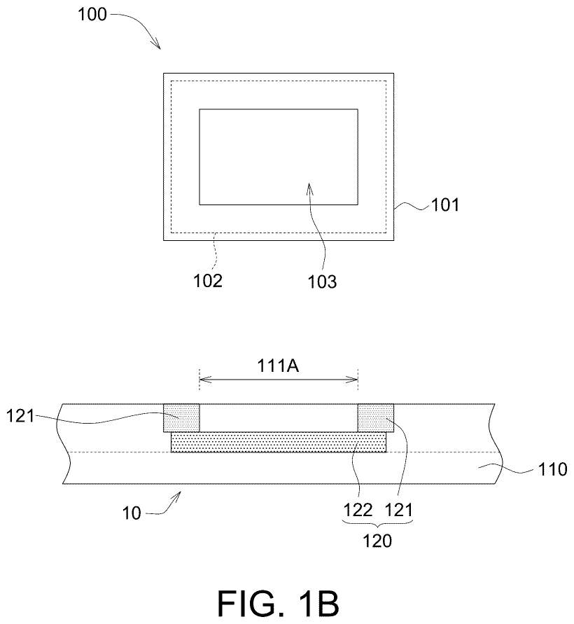

FIG. 1A is a diagram illustrating the process for fabricating an isolation pattern module 100, according to one embodiment of the present disclosure. The isolation pattern module 100 includes a first sub-isolation-pattern 101 and a second sub-isolation-pattern 102. Each of the first sub-isolation-pattern 101 includes a plurality of different pattern units 101a, and each of the different pattern unit 101a has a pitch boundary 101p. By combining and splicing the pitch boundaries 101p of the plurality of different pattern units 101a, a rectangular closed area 103 can be defined, wherein the second sub-isolation pattern 102 corresponds to the pitch boundary 101p of the plurality of different pattern unit 101a and overlaps the closed area 103. In one embodiment of the disclosure, the pitch boundary 101p may be (but not limited to) a processing pitch for forming the metal line in the semiconductor device of the integrated circuit 10.

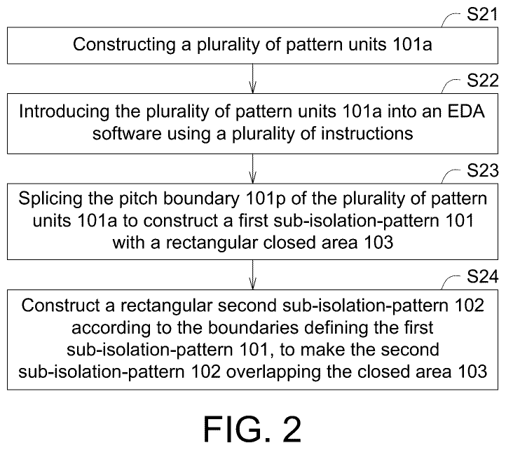

FIG. 2 is a diagram illustrating the flow chart of the method for fabricating the isolation pattern module 100 as depicted in FIG. 1A. The method for fabricating the isolation pattern module 100 (including the first sub-isolation pattern 101 and the second sub-isolation pattern 102) includes the following steps:

Firstly (refer to step S21), a plurality of different pattern units 101a are consctucted. In this embodiment, the different pattern units 101a may be a plurality of pattern units 101a with the same size but different arrangement positions, directions, angles or ways.

Next (refer to step S22), the plurality of different pattern units 101a are introduced into an EDA system using a plurality of instructions. Then (refer to step S23), the pitch boundaries 101p of these different pattern units 101a are spliced and combined to construct a first sub-isolation pattern 101 shaped as a closed ring (for example, a rectangular closed ring), thereby a closed area. 103 is defined. Then referring to step S24, a second sub-isolation pattern 102 (for example, rectangular in shape) is constructed according to the splicing boundary of the first sub-isolation pattern 101, so as to make the second sub-isolation pattern 102 overlapping the closed area 103.

Next, refer to FIG. 1B; the sub-isolation patterns (including the first sub-isolation pattern 101 and the second sub-isolation pattern 102) of the isolation pattern module 100 are respectively transferred to the photoresist layer (not shown), and using the patterned photoresist layer (not shown) as a mask, through an ion implantation process, a first well region 121 corresponding to the first sub-isolation pattern 101 and a second well region 122 corresponding to the second sub-isolation pattern 102 are formed in the semiconductor substrate 110. The first well region 121 can define a closed circuit region 111A in the semiconductor substrate 110; and the second well region 122 can overlap the closed circuit region 111A to form an isolation structure 120.

For example, as shown in FIG. 1B, the second well region 122 is a deep N well region having an n-type electrical property located below the first well region 121. The second well region 122 overlaps the circuit region 111A and is connected to the first well region 121 to form a isolation structure surrounding the circuit region 111A. Of note that, in the embodiments of the present disclosure, the order of the ion implantation processes used to form the first well region 121 and the second well region 122 is not limited. Those with ordinary skill in the art can choice the implantation order according to the process arrangements and requirements.

Subsequently, a series of downstream processes, such as the process for forming a plurality of semiconductor devices (not shown) and the metal interconnection process for forming an interconnect structure (not shown), are performed above the circuit area 111A, finally completing the production of the integrated circuit 10 (such as, a digital circuit, an analog circuit or a combination thereof).

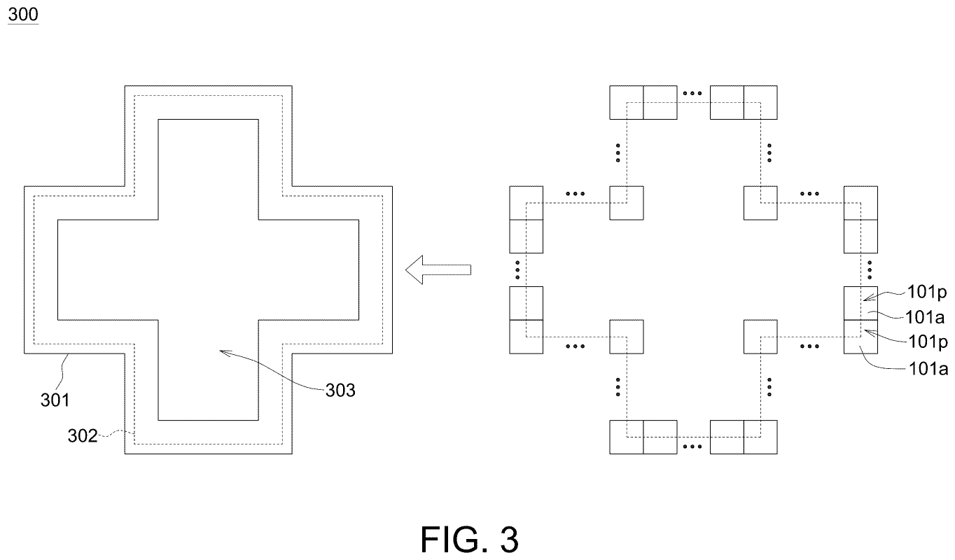

However, the shapes of the mask patterns (e.g., the first sub-isolation pattern 101 and the second sub-isolation pattern 102) of the isolation pattern module 100 are not limited to rectangles. For example, FIG. 3 is a diagram illustrating the process for fabricating an isolation pattern module 300, according to another embodiment of the present disclosure. The first sub-isolation pattern 301 of the isolation pattern module 300 may be a polygonal closed ring (e.g., cross-ring-shaped) pattern composed of a plurality of pattern units 101a arranged in different ways. In this embodiment, the pitch boundaries of the plurality of pattern units 101a in different arrangements are combined to construct a closed cross-ring-shaped first sub-isolation pattern 301, so as to define a closed area 303. Afterwards, a cross-shaped second sub-isolation pattern 302 is constructed according to the splicing boundary defining the first sub-isolation pattern 301, wherein the second sub-isolation pattern 302 overlaps the closed area 303.

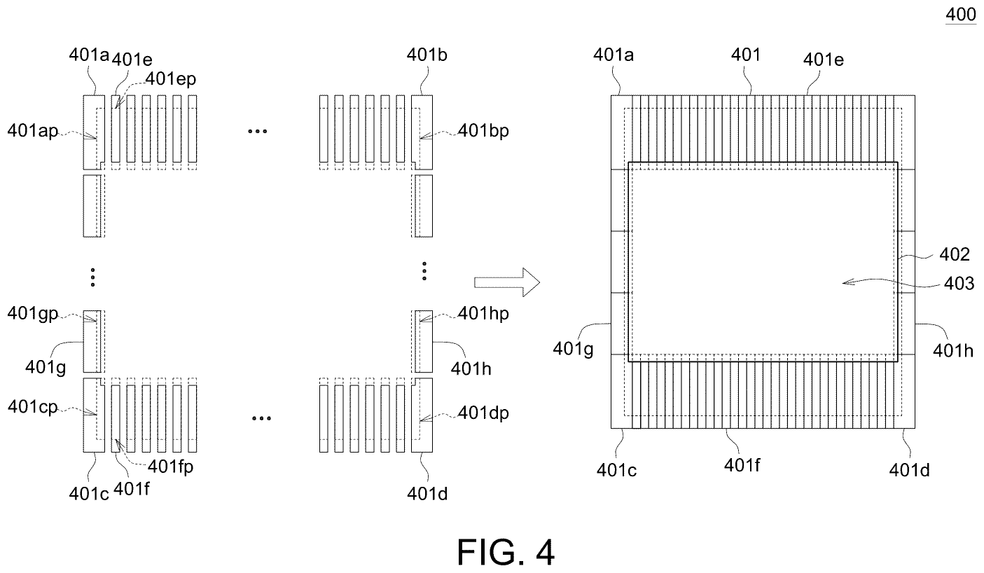

In yet another embodiment of the present disclosure, the isolation pattern module 400 may include a plurality types of pattern units with different sizes and shapes, such as eight types of pattern units 401a, 401b, 401c, 401d, 401e, 401f, 401g and 401h. Please refer to FIG. 4, which is a diagram illustrating the process for fabricating an isolation pattern module 400, according to yet another embodiment of the present disclosure. Each type of the pattern units 401a, 401b, 401c, 401d, 401e, 401f, 401g and 401h has its pitch boundary respectively designated as 401ap, 401bp, 401cp, 401dp, 401ep, 401fp, 401gp and 401hp. Although these pitch boundaries 401ap, 401bp, 401cp, 401dp, 401ep, 401fp, 401gp and 401hp of different types of the pattern units 401a, 401b, 401c, 401d, 401e, 401f, 401g and 401h has the same size and shape, but the designer can couture the mask pattern (the first sub-isolation pattern 401 and the second sub-isolation pattern 402) with different shapes and sizes by selecting different numbers and different types of the pattern units 401a, 401b, 401c, 401d, 401e, 401f, 401g, and 401h and/or arranging angles thereof.

For example, in the present embodiment, the upper, lower, left and right corners of a plane can be respectively arranged one corner pattern unit (e.g., the pattern unit 401a, 401b, 401c and 401d) can be. A plurality of pattern units 401e are arranged between the two corner pattern units 401a and 401b; a plurality of pattern units 401f are arranged between the two corner pattern units 401c and 401d; a plurality of pattern units 401g are arranged between the two corner pattern units 401a and 401c; and a plurality of pattern units 401h are arranged between the two corner pattern units 401b and 401d. Each type of pattern units 401a, 401b, 401c, 401d, 401e, 401f, 401g and 401h are arranged along the same angle. A closed rectangular ring-shaped first sub-isolation pattern 401 can be constructed by splicing the pitch boundaries 401ap, 401bp, 401cp, 401dp, 401ep, 401fp, 401gp and 401hp of the pattern units 401a, 401b, 401c, 401d, 401e, 401f, 401g, and 401h, so as to define a closed area 403. Next, a rectangular second sub-isolation pattern 402 is constructed according to the splicing boundaries defining the first sub-isolation pattern 401, and the second sub-isolation pattern 402 overlaps the closed area 403.

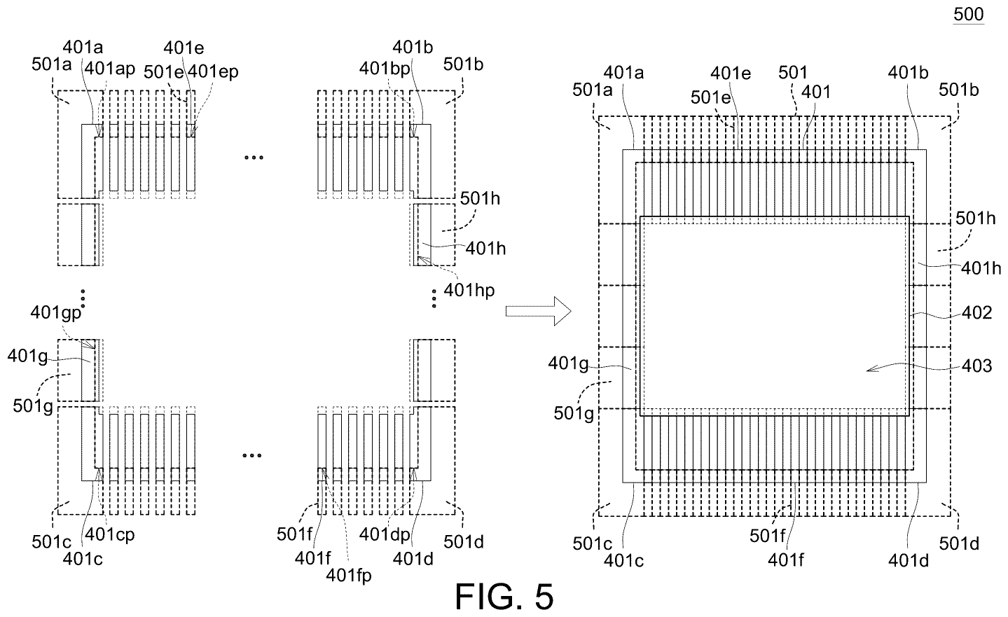

FIG. 5 is a diagram illustrating the process for fabricating an isolation pattern module 500, according to a further embodiment of the present disclosure. The structure of the isolation pattern module 500 is similar to that of the isolation pattern module 400. The difference is that the isolation pattern module 500 additionally (optionally) includes another 8 types of pattern units 501a, 501b, 501c, 501d, 501e, 501f, 501g and 501h respectively correspond to one of the pattern units 401a, 401b, 401c, 401d, 401e, 401f, 401g and 401h. And each pattern unit 501a, 501b, 501c, 501d, 501e, 501f, 501g or 501h is connected to a side of its corresponding pattern unit 401a, 401b, 401c, 401d, 401e, 401f, 401g or 401h away from the closed areas 403, so as to form a third sub-isolation pattern 501 outside the first sub-isolation pattern 401.

According to the above embodiments, an isolation pattern module, a fabrication method thereof, and a method for manufacturing an isolation pattern are provided by the present disclosure. An EDA software is used to construct at least one pattern unit (cell) according to the processing pitch, to make each of the pattern units having a pitch boundary. Next, a first sub-isolation pattern is formed by splicing the plurality of pattern units, in which the pitch boundaries of two adjacent pattern units are connected to each other to define a closed area. Subsequently, a second sub-isolation pattern is formed based on and overlapped with the closed area. The first sub-isolation pattern and the second sub-isolation pattern together form an isolation pattern module.

By using at least one standard cell designed from the beginning serving as a pattern unit, and in combine with the EDA system, at least one sub-isolation pattern can be formed more effectively through splicing a plurality of standard cells (pattern units). Multiple sub-isolation patterns can be then combined to form an isolation pattern module used to form isolation elements in a semiconductor substrate. It has the advantages of reducing manual operations, increasing the pattern design flexibility and variability, and improving the accuracy and margin (process window) of integrated circuits (ICs) manufacturing.

In one embodiment of the present disclosure, the solation pattern module includes a first sub-isolation pattern and a second sub-isolation pattern, by which a first well corresponding to the first sub-isolation pattern can be formed in a semiconductor substrate to define a closed circuit area; and a second well area corresponding to the second sub-isolation pattern below the first well can be formed to overlap the closed circuit area; thereby an isolation structure can be prepared.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An isolation pattern module, comprising:
a first sub-isolation-pattern, having a plurality of pattern units, and each of the pattern units has a pitch boundary to define a closed area; and
a second sub-isolation-pattern, corresponding to the pitch boundary of each of the pattern units and overlapping the closed area.

2. The isolation pattern module according to claim 1, wherein the pitch boundary is a processing pitch of a semiconductor device.

3. The isolation pattern module according to claim 2, wherein the semiconductor device comprises:
an isolation structure, comprising:
a first well region, formed in a semiconductor substrate and corresponding to the first sub-isolation pattern for defining a circuit region in the semiconductor substrate corresponding to the closed region;
a second well region, formed in the semiconductor substrate, disposed below the first well region, corresponding to the second sub-isolation pattern, and overlapping the circuit region; and
an integrated circuit, disposed in the circuit area.

4. The isolation pattern module according to claim 3, wherein the integrated circuit comprises a digital circuit, an analog circuit or a combination thereof.

5. The isolation pattern module according to claim 1, wherein the plurality of pattern units comprises:
a first pattern unit adjacent to the closed area; and
a second pattern unit connected to one side of the first pattern unit away from the closed area.

6. The isolation pattern module according to claim 1, wherein the closed area comprises a polygon area.

7. The isolation pattern module according to claim 6, wherein the plurality of pattern units comprises at least one first type pattern unit and at least one second type pattern unit, the polygon area is constructed by the at least one first type pattern unit and the at least one second type pattern unit.

8. A method for fabricating an isolation pattern module, comprising:
constructing a plurality of pattern units, and each of the pattern units has a pitch boundary;
splicing the plurality of pattern units to construct a first sub-isolation-pattern, and defining a closed area according the pitch boundary of each of the plurality of pattern units; and
constructing a second sub-isolation-pattern according to the closed area and overlapping the closed area.

9. The method according to claim 8, wherein the construction of the sub-isolation-pattern and the first second sub-isolation-pattern comprises using an electronic design automation (EDA) system.

10. A method for manufacturing an isolation pattern, comprising:
constructing a plurality of pattern units;
introducing the plurality of pattern units into an EDA system using a plurality of instructions;
combining the plurality of pattern units to construct a first sub-isolation pattern and define a closed area; and
constructing a second sub-isolation-pattern according to the closed area and overlapping the closed area.
